(19) United States
(12) Patent Application Publication
(10) Pub. No.: US 2026/0047508 A1
(43) Pub. Date: Feb. 12, 2026

(54) SEMICONDUCTOR PACKAGE

(71) Applicant: Samsung Electronics Co., Ltd., Suwon-si (KR)

(72) Inventor: Jae Woon KIM, Suwon-si (KR)

(21) Appl. No.: 19/180,250

(22) Filed: Apr. 16, 2025

(30) Foreign Application Priority Data
Aug. 8, 2024 (KR) 10-2024-0106093

(51) Int. Cl. H01L 23/498; H01L 23/00; H01L 23/15; H01L 23/373; H01L 23/538; H01L 25/18; H10B 80/00; H10D 80/30

(52) U.S. Cl. CPC H01L 23/49833; H01L 23/15; H01L 23/3735; H01L 23/49838; H01L 23/5385; H01L 23/5386; H01L 24/16; H01L 25/18; H01L 2224/16227; H01L 2224/16238; H10B 80/00; H10D 80/30

(57) ABSTRACT

A semiconductor package according to embodiments of the present disclosure includes a first redistribution substrate, a semiconductor chip and a connection support structure on the first redistribution substrate, wherein the semiconductor chip is a logic chip or a memory chip, and a molding film above the first redistribution substrate. The connection support structure is horizontally spaced apart from the semiconductor chip and horizontally overlaps the semiconductor chip. The connection support structure includes a glass substrate and a vertical conductive pillar penetrating the glass substrate.

### CROSS-REFERENCE TO RELATED APPLICATIONS

This U.S. non-provisional patent application claims priority under 35 U.S.C. § 119 of Korean Patent Application No. 10-2024-0106093, filed on Aug. 8, 2024, the entire contents of which are hereby incorporated by reference.

### BACKGROUND

The present disclosure herein relates to a semiconductor package.

An integrated circuit chip is packaged into a semiconductor package to have a suitable form to be installed in an electronic device. In general, in a semiconductor package, a semiconductor chip is mounted on a printed circuit board, and the semiconductor chip and the printed circuit board are electrically connected to each other using bonding wires or bumps. With the development of the electronics industry, various research is being carried out to improve the reliability of semiconductor packages.

### SUMMARY

The present disclosure provides a semiconductor package with improved reliability.

An embodiment of the inventive concept provides a semiconductor package including: a first redistribution substrate; a semiconductor chip and a connection support structure on the first redistribution substrate, wherein the semiconductor chip is a logic chip or a memory chip; and a molding film above the first redistribution substrate, wherein the connection support structure is horizontally spaced apart from the semiconductor chip and horizontally overlaps the semiconductor chip, and wherein the connection support structure includes: a glass substrate; and a vertical conductive pillar penetrating the glass substrate.

In an embodiment of the inventive concept, a semiconductor package includes: a first redistribution substrate, wherein the semiconductor chip is a logic chip or a memory chip; a semiconductor chip and a connection support structure on the first redistribution substrate; a second redistribution substrate on the semiconductor chip and the connection support structure; and a molding film between the first redistribution substrate and the second redistribution substrate, wherein the connection support structure is horizontally spaced apart from the semiconductor chip and horizontally overlaps the semiconductor chip, and wherein the connection support structure includes: a glass substrate; and a vertical conductive pillar penetrating the glass substrate, wherein an upper surface of the glass substrate is in contact with a lower surface of the second redistribution substrate, and wherein a lower surface of the glass substrate is spaced apart from an upper surface of the first redistribution substrate.

In an embodiment of the inventive concept, a semiconductor package includes: a first redistribution substrate; a first semiconductor chip and a connection support structure on the first redistribution substrate, wherein the semiconductor chip is a logic chip or a memory chip; a second substrate on the first semiconductor chip and the connection support structure; a molding film between the first redistribution substrate and the second substrate; a second semiconductor chip and a heat dissipation structure on the second substrate; a first connection terminal between the first semiconductor chip and the first redistribution substrate; and a second connection terminal between the connection support structure and the first redistribution substrate, wherein the connection support structure is horizontally spaced apart from the first semiconductor chip, wherein the heat dissipation structure is horizontally spaced apart from the second semiconductor chip, and wherein the connection support structure includes: a glass substrate; and a vertical conductive pillar penetrating the glass substrate, wherein the heat dissipation structure vertically overlaps the first semiconductor chip, and wherein the molding film covers an upper surface and a lower surface of the first semiconductor chip, a side surface of the connection support structure, a side surface of the first connection terminal, and a side surface of the second connection terminal.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a plan view of a semiconductor package according to some embodiments;

FIG. 2 is a cross-sectional view taken along line I-I′ of FIG. 1;

FIG. 3 is an enlarged view of portion A1 of FIG. 2;

FIG. 4 is an enlarged view of portion A2 of FIG. 2;

FIG. 5 is a cross-sectional view of a semiconductor package according to some embodiments;

FIG. 6 is an enlarged view of portion A1 of FIG. 5;

FIG. 7 is a cross-sectional view of a semiconductor package according to some embodiments;

FIG. 8 is a plan view of a semiconductor package according to some embodiments;

FIG. 9 is a cross-sectional view taken along line I-I′ of FIG. 8;

FIG. 10 is a plan view of a semiconductor package according to some embodiments;

FIG. 11 is a cross-sectional view taken along line I-I′ of FIG. 10;

FIG. 12 is a plan view of a semiconductor package according to some embodiments;

FIG. 13 is a cross-sectional view taken along line I-I′ of FIG. 12;

FIG. 14 is a plan view of a semiconductor package according to some embodiments;

FIG. 15 is a cross-sectional view taken along line I-I′ of FIG. 14;

FIGS. 16A, 16B, 16C, 16D, and 16E are diagrams illustrating a manufacturing process of a connection support substrate according to some embodiments;

FIGS. 17A and 17B are diagrams illustrating a manufacturing process of a connection support substrate according to some embodiments; and

FIGS. 18A, 18B, 18C, 18D, and 18E are diagrams illustrating a manufacturing process of a semiconductor package according to some embodiments.

### DETAILED DESCRIPTION

In the present disclosure, like reference numerals may refer to like elements throughout. A semiconductor package and a method for manufacturing the same according to the inventive concept will be described.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Spatially relative terms, such as “beneath,” “below,” “lower,” “above,” “upper,” “top,” “bottom,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

Items described in the singular herein may be provided in plural, as can be seen, for example, in the drawings. Thus, the description of a single item that is provided in plural should be understood to be applicable to the remaining plurality of items unless context indicates otherwise.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

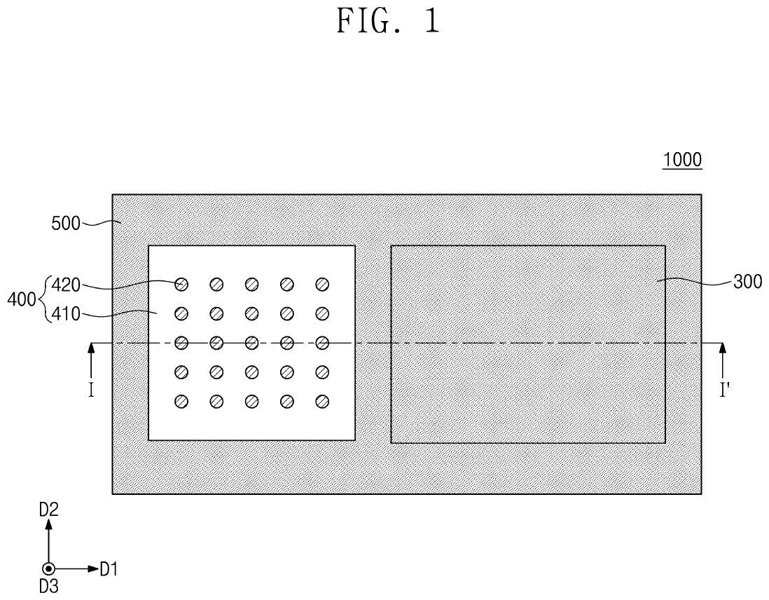

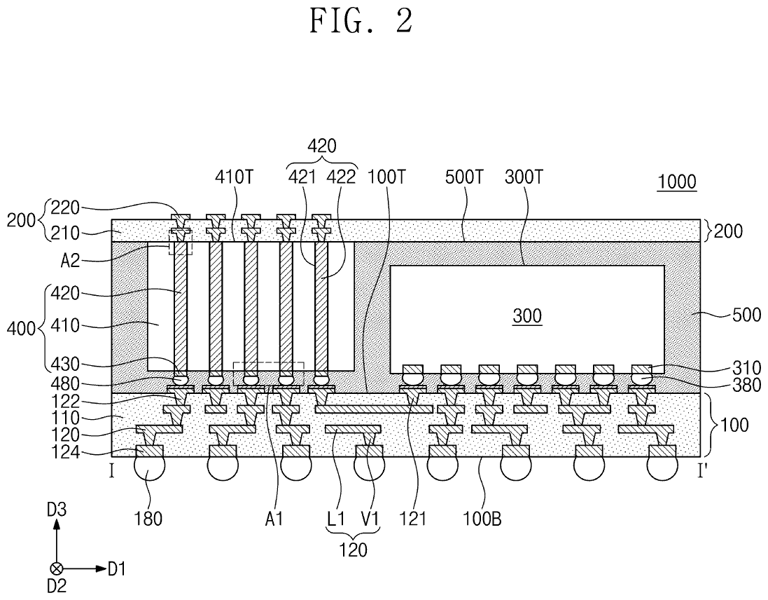

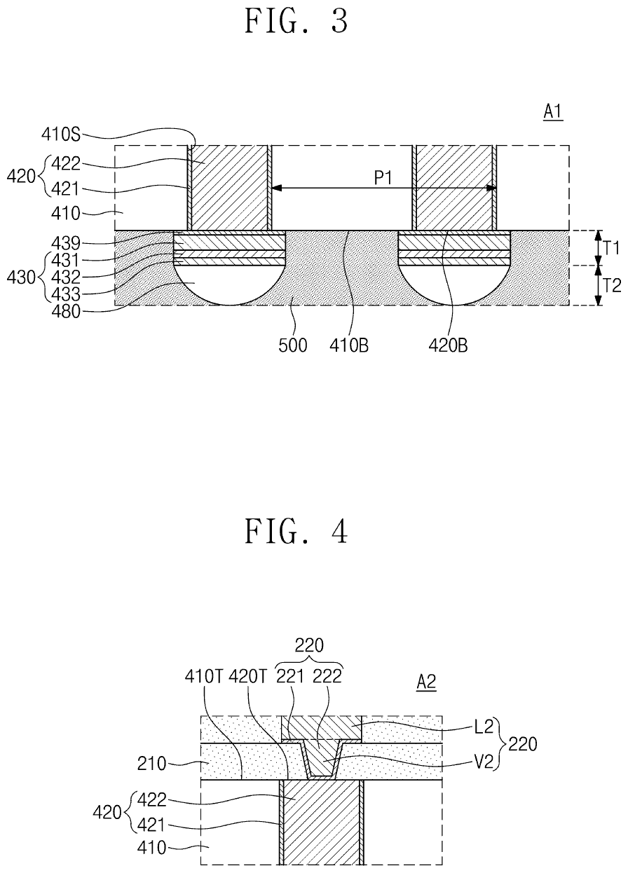

FIG. 1 is a plan view of a semiconductor package according to some embodiments. FIG. 2 is a cross-sectional view taken along line I-I′ of FIG. 1. FIG. 3 is an enlarged view of portion A1 of FIG. 2. FIG. 4 is an enlarged view of portion A2 of FIG. 2.

Referring to FIGS. 1 and 2, a semiconductor package 1000 may include a first redistribution substrate 100, a second redistribution substrate 200, a semiconductor chip 300, a connection support structure 400 (also referred to as a connection support), and a molding film 500.

The first redistribution substrate 100 may include a first insulating layer 110, a first redistribution pattern 120, a first bonding pad 121, a second bonding pad 122, and an under bump pattern 124. In the present disclosure, a first direction D1 may be one direction parallel with an upper surface 100T of the first redistribution substrate 100. A second direction D2 may be one direction parallel with the upper surface 100T of the first redistribution substrate 100 and intersecting (e.g., perpendicular to) the first direction D1. A third direction D3 may be one direction perpendicular to the upper surface 100T of the first redistribution substrate 100 and to the first direction D1 and the second direction D2. The first direction D1 and the second direction D2 may be referred to as horizontal directions. The third direction D3 may be referred to as a vertical direction. The upper surface 100T of the first redistribution substrate 100 may be a surface with which the first insulating layer 110 and the molding film 500 are in contact.

In some examples, the first redistribution substrate 100 and/or first redistribution pattern 120, may redistribute signals horizontally between the bottom and the top (e.g., the upper surface 100T) of the first redistribution substrate 100. In other examples, a substrate may pass signals through vertically between the bottom and top of the first redistribution substrate 100, without horizontally redistributing the signals.

The first insulating layer 110 may include a photoimageable dielectric (PID). The PID may include, for example, a polymer material such as benzocyclobutene (BCB). The first insulating layer 110 is illustrated as a single layer, but may include a plurality of layers actually.

The first redistribution pattern 120 may be disposed in the first insulating layer 110. The first bonding pad 121 and the second bonding pad 122 may be arranged in an upper portion of the first redistribution substrate 100 and upper surfaces thereof may be exposed from the first insulating layer 110. The under bump pattern 124 may be disposed in a lower portion of the first redistribution substrate 100 and a lower surface thereof may be exposed from the first insulating layer 110. The first bonding pad 121, the second bonding pad 122, and the under bump pattern 124 may be electrically connected to the first redistribution pattern 120. The first redistribution pattern 120 may include a first line portion L1 and a first via portion V1. The first line portion L1 may extend in the first direction D1 and/or the second direction D2. The first via portion V1 may be disposed under the first line portion L1. The first via portion V1 may have a shape tapered from the upper surface 100T to a lower surface 100B of the first redistribution substrate 100. The first via portion V1 may electrically connect the first line portions L1 of the redistribution patterns 120 adjacent to each other in the third direction D3.

The first redistribution pattern 120, the first bonding pad 121, the second bonding pad 122, and the under bump pattern 124 may include a first seed pattern and a first conductive pattern on the first seed pattern. For example, the first seed pattern may include copper/titanium, and the first conductive pattern may include copper. The first bonding pad 121 and the second bonding pad 122 may further include additional layers of metal such as nickel and gold on the conductive pattern.

An external connection terminal 180 may be disposed on the lower surface 100B of the first redistribution substrate 100. The external connection terminal 180 may include a solder ball or the like. At least some of the external connection terminals 180 may be arranged in a diagonal direction with respect to the semiconductor chip 300. For example, the semiconductor package 1000 may be a fan-out package, or the like.

The semiconductor chip 300 and the connection support structure 400 may be arranged on the first redistribution substrate 100. The semiconductor chip 300 and the connection support structure 400 may be spaced apart from each other in the first direction D1 (e.g., may be horizontally spaced apart from each other). In addition, the semiconductor chip 300 and the connection support structure 400 may horizontally overlap each other. For example, the ranges of vertical coordinates of the semiconductor chip 300 and the connection support structure 400 may at least partially overlap, and/or the semiconductor chip 300 and the connection support structure 400 may have at least partially overlapping vertical levels above the first redistribution substrate.

The semiconductor chip 300 may include, for example, at least one of a logic chip or a memory chip. For example, the semiconductor chip 300 may be a memory chip such as any one of a DRAM, SRAM, NAND-FLASH, or another non-volatile or volatile memory chip, or may be a logic chip such as any one of a central processing unit (CPU), graphics processing unit (GPU), and application specific integrated circuit (ASIC), or other processor or controller chip. The semiconductor chip 300 may include a chip pad 310. A first connection terminal 380 may be disposed between the chip pad 310 and the first bonding pad 121. The first connection terminal 380 may include, for example, at least one of a bump, a pillar, or a solder ball. The first connection terminal may include, for example, tin (Sn).

The connection support structure 400 may include a glass substrate 410, a vertical conductive pillar 420, and a connection pad 430. The connection support structure 400 differs from an interposer or bridge in not including a separate wiring layer on an upper surface 410T or lower surface of the glass substrate 410 or a line extending in a horizontal direction. The connection support structure 400 differs from a printed circuit board (PCB) in not including stacked vias and arranged lines between the upper surface and the lower surface. The connection support structure 400 differs from a semiconductor chip in not including a separate integrated circuit such as a transistor. The connection support structure 400 may serve to connect the first redistribution substrate 100 and the second redistribution substrate 200, and mechanically support the semiconductor package 1000. The glass substrate 410 may include at least one of borosilicate glass, aluminosilicate glass, or quartz glass. For example, the glass substrate 410 may be quartz glass including high-purity silicon dioxide (SiO₂). A level of the upper surface 410T of the glass substrate 410 may be higher than a level of the upper surface 300T of the semiconductor chip 300. For example, a highest level of the glass substrate 410 may be higher (e.g., in the vertical direction D3) than a highest level of the semiconductor chip 300. The upper surface 410T of the glass substrate 410 may be in contact with a lower surface of the second redistribution substrate 200. A lower surface of the glass substrate 410 may be spaced apart from the upper surface 100T of the first redistribution substrate 100. The vertical conductive pillar 420 may penetrate the glass substrate 410 in the third direction D3. The vertical conductive pillar 420 may also be referred to as a through glass via (TGV). The vertical conductive pillar 420 may be one of a plurality of vertical conductive pillars (e.g., may be provided in plurality) and arranged at a regular pitch along the first direction D1 and the second direction D2. A height of the vertical conductive pillar 420 may be at least about 50 μm. For example, the height of the vertical conductive pillar 420 may be about 100 μm. For another example, the height of the vertical conductive pillar 420 may be about 200 μm. An aspect ratio obtained by dividing the height of the vertical conductive pillar 420 by a diameter of the vertical conductive pillar 420 in the first direction D1 or the second direction D2 may be larger than 3. A side surface of the vertical conductive pillar 420 may be parallel with the third direction D3. For example, the vertical conductive pillar 420 may not have a tapered shape with a width that increases or decreases in the third direction D3. The vertical conductive pillar 420 may have a near cylindrical shape with a constant width along the third direction D3. An upper surface shape and a lower surface shape of the vertical conductive pillar 420 may be substantially the same, and an upper surface size and a lower surface size of the vertical conductive pillar 420 may be substantially the same. The vertical conductive pillar 420 may be formed as a single piece along the third direction D3, and may not form a shape in which a plurality of vertical conductive pillars 420 are stacked in the third direction D3.

Referring to FIG. 3, the vertical conductive pillar 420 may include a vertical seed pattern 421 and a vertical conductive pattern 422. The vertical seed pattern 421 may be interposed between an inner wall 410S of the glass substrate 410 and the vertical conductive pattern 422. For example, the vertical seed pattern 421 may include copper/titanium, and the vertical conductive pattern 422 may include copper. The vertical conductive pillars 420, for example, may be spaced according to a first pitch P1. The first pitch P1 may be larger than 0 μm and equal to or less than about 90 μm.

The connection pad 430 may be disposed on a lower surface of the vertical conductive pillar 420. For example, a diameter of the connection pad 430 may be larger than a diameter of the vertical conductive pillar 420. Alternatively, according to some embodiments, the diameter of the connection pad 430 may be equal to or less than the diameter of the vertical conductive pillar 420. The connection pad 430 may include a lower seed pattern 439, a first metal pattern 431, a second metal pattern 432, and a third metal pattern 433. The lower seed pattern 439 may be in contact with the lower surface of the vertical conductive pillar 420. The first metal pattern 431 and the second metal pattern 432 may be sequentially stacked on the lower seed pattern 439. A thickness of the first metal pattern 431 may be larger than a thickness of the second metal pattern 432 and a thickness of the third metal pattern 433. For example, the thickness of the first metal pattern 431 may be about 8 μm, the thickness of the second metal pattern 432 may be about 3 μm, and the thickness of the third metal pattern 433 may be about 3 μm. The first metal pattern 431 and the second metal pattern 432 may include different metals. The second metal pattern 432 and the third metal pattern 433 may include different metals. For example, the lower seed pattern 439 may include copper/titanium, the first metal pattern 431 may include copper, the second metal pattern 432 may include nickel, and the third metal pattern 433 may include copper. A second connection terminal 480 may be disposed on the connection pad 430. The second connection terminal 480 may include a solder including tin (Sn) and silver (Ag). The second connection terminal 480 may be interposed between the second bonding pad 122 and the connection pad 430. The connection pad 430 may have a first thickness T1 in the third direction D3, and the second connection terminal 480 may have a second thickness T2 in the third direction D3. The second thickness T2 may be larger than the first thickness T1 and equal to or less than two times the first thickness T1. For example, the second thickness T2 may be about 21 μm, and the first thickness T1 may be about 14 μm. The connection support structure 400 may be electrically connected to the first redistribution substrate 100 through the second connection terminal 480.

The molding film 500 may be disposed on the first redistribution substrate 100. The molding film 500 may cover an upper surface and side surface of the semiconductor chip 300 and an outer surface of the connection support structure 400. The molding film 500 may cover a side surface of the first connection terminal 380 and a side surface of the second connection terminal 480. The molding film 500 may extend between the glass substrate 410 and the first redistribution substrate 100 and between the semiconductor chip 300 and the first redistribution substrate 100. The molding film 500 may be in contact with the lower surface of the glass substrate 410. The molding film 500 may include, for example, an insulating material such as an epoxy molding compound (EMC).

The second redistribution substrate 200 may be disposed on the molding film 500 and the connection support structure 400. The second redistribution substrate 200 may include a second insulating layer 210 and a second redistribution pattern 220. The second insulating layer 210 may include a material that is the same as or similar to that of the first insulating layer 110. In some examples, the second redistribution substrate 200 and/or second redistribution pattern 220, may redistribute signals horizontally between the bottom (e.g., the upper surface 410T of glass substrate 410) and the top of the second redistribution substrate 200. In other examples, a substrate may pass signals through vertically between the bottom and top of the second redistribution substrate 200, without horizontally redistributing the signals.

Referring to FIG. 4, the second redistribution pattern 220 may include a second seed pattern 221 and a second conductive pattern 222. For example, the second seed pattern 221 may include copper/titanium, and the second conductive pattern 222 may include copper. The second conductive pattern 222 may be disposed on the second seed pattern 221. The second redistribution pattern 220 may include a second line portion L2 and a second via portion V2. The second line portion L2 may extend in the first direction D1 and/or the second direction D2. The second via portion V2 may be integrally connected to the second line portion L2 and may narrow toward the vertical conductive pillar 420. The second redistribution patterns 220 may be arranged more densely in a region on the connection support structure 400 than in a region on the semiconductor chip 300. According to some embodiments, stacked second redistribution patterns 220 may have a shape in which vias not extending to the region on the semiconductor chip 300 are stacked.

An upper surface 420T of the vertical conductive pillar 420 may be coplanar with the upper surface 410T of the glass substrate 410. A level of the upper surface 420T of the vertical conductive pillar 420 may be substantially the same as the level of the upper surface 410T of the glass substrate 410. The upper surface 420T of the vertical conductive pillar 420 may be in contact with a lower surface of the second via portion V2 of the second redistribution pattern 220. When the upper surface 420T of the vertical conductive pillar 420 is not fully covered with the lower surface of the second via portion V2, a remainder portion may be in contact with the second insulating layer 210. Referring back to FIG. 2, the upper surface 410T of the glass substrate 410 may be coplanar with an upper surface 500T of the molding film 500. The level of the upper surface 410T of the glass substrate 410 may be substantially the same as a level of the upper surface 500T of the molding film 500.

A coefficient of thermal expansion (CTE) of the semiconductor chip 300 may range from about 3.2 ppm/° C. to about 4.2 ppm/° C. For example, the coefficient of thermal expansion of the semiconductor chip 300 may be about 3.4 ppm/° C. The coefficient of thermal expansion of the glass substrate 410 may be about 3.2 ppm/° C. to about 4.2 ppm/° C. or may be similar thereto. The coefficient of thermal expansion of the molding film 500 may be about 6 ppm/° C. to about 20 ppm/° C. When comparing a first difference between the coefficient of thermal expansion of the semiconductor chip 300 and the coefficient of thermal expansion of the molding film 500 with a second difference between the coefficient of thermal expansion of the semiconductor chip 300 and the coefficient of thermal expansion of the glass substrate 410, the second difference may be significantly smaller than the first difference.

A semiconductor package according to the inventive concept may include a connection support structure including a glass substrate and a vertical conductive pillar as a means for electrically connecting a first redistribution substrate and a second redistribution substrate. The disclosed glass substrate may provide advantages, such as having more similar material properties to a semiconductor chip compared with a portion of a molding film or a copper post region. For example, since a difference in the coefficient of thermal expansion between the glass substrate and a semiconductor chip is small, the connection support structure may prevent warpage due to thermal stress compared to the case where the corresponding region is filled with a molding film. Furthermore, the vertical conductive pillar in the glass substrate may have a higher height and aspect ratio compared to the vertical conductive pillar in the molding film. Therefore, it may be possible to form the vertical conductive pillars densely even when a height of the semiconductor chip 300 is increased or a pitch thereof is reduced. Thus, the disclosed glass substrate may also provide significant freedom in TGV design.

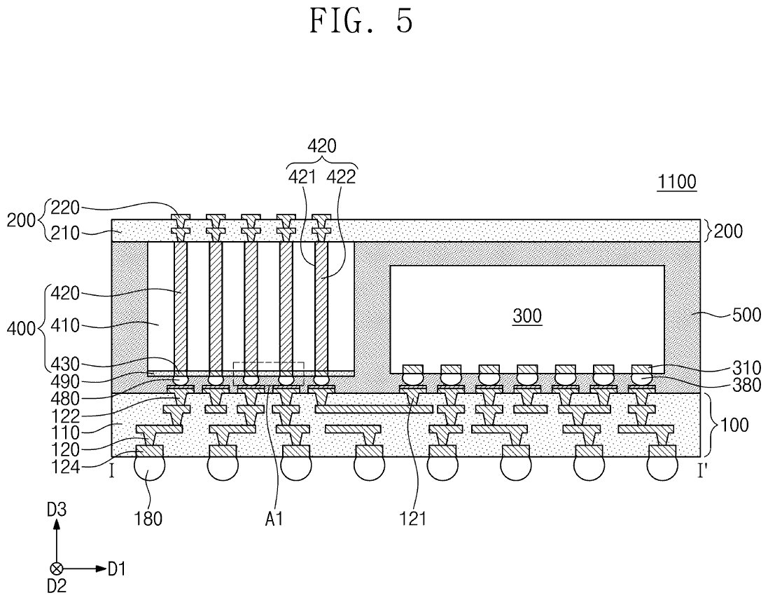

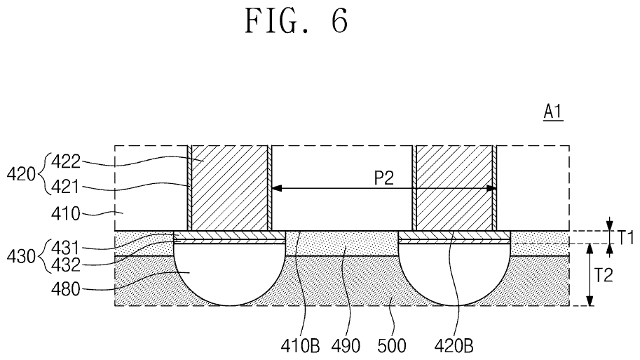

FIG. 5 is a cross-sectional view of a semiconductor package 1100 according to some embodiments. FIG. 5 is a cross-sectional view taken along line I-I′ of FIG. 1. FIG. 6 is an enlarged view of portion A1 of FIG. 5. Most of the above description with reference to FIGS. 1, 2, and 4 may be applicable in the same or similar manner to the semiconductor package 1100 of FIGS. 5 and 6. Thus, descriptions overlapping with the above descriptions provided with reference to FIGS. 1, 2, and 4 will not be provided.

Referring to FIGS. 5 and 6, the connection support structure 400 may further include a protective pattern 490 disposed on a lower surface 410B of the glass substrate 410. The protective pattern 490 may include, for example, a photosensitive solder resist (PSR) material. The molding film 500 may be in contact with a lower surface of the protective pattern 490. The vertical conductive pillars 420 may be spaced in the first direction D1 and/or the second direction D2 according to a second pitch P2. The second pitch P2 may be about 90 μm to about 130 μm. The second pitch P2 may be larger than the first pitch P1 described with reference to FIG. 3.

The connection pad 430 may not include the lower seed pattern 439. The connection pad 430 may include the first metal pattern 431 that is in contact with the lower surface of the vertical conductive pillar 420 and the second metal pattern 432 on the first metal pattern 431. A thickness of the first metal pattern 431 may be larger than a thickness of the second metal pattern 432. For example, the thickness of the first metal pattern 431 may be about 3 μm, and the thickness of the second metal pattern 432 may be about 0.3 μm. The first metal pattern 431 and the second metal pattern 432 may include different metals. For example, the first metal pattern 431 may include nickel, and the second metal pattern 432 may include gold. The second connection terminal 480 may be disposed on a lower surface of the second metal pattern 432. The second thickness T2 of the second connection terminal 480 may be at least seven times larger than the first thickness T1 of the connection pad 430. For example, the first thickness T1 may be about 3.3 μm, and the second thickness T2 may be about 31 μm. A thickness of the protective pattern 490 may be larger than the first thickness T1 of the connection pad 430 and smaller than the second thickness T2 of the second connection terminal 480.

When comparing the embodiment of FIG. 4 with the embodiment of FIG. 6, a difference between the first thickness T1 and the second thickness T2 may be small in a range of small pitch such as the first pitch P1, such as in the embodiment of FIG. 4. In a range of relatively large pitch such as the second pitch P2, the difference between the second thickness T2 and the first thickness T1 may be large, such as in the embodiment of FIG. 6.

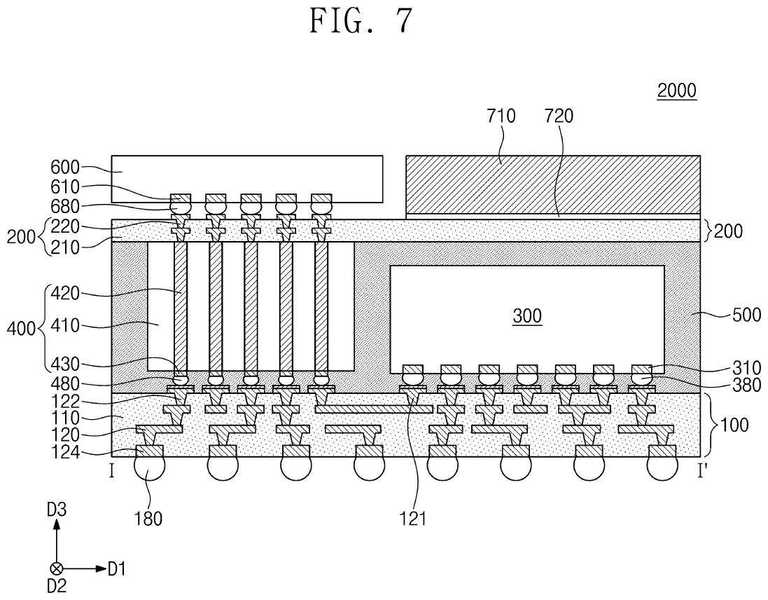

FIG. 7 is a cross-sectional view of a semiconductor package 2000 according to some embodiments. Most of the above description with reference to FIGS. 1 to 4 may be applicable in the same or similar manner to the semiconductor package 2000 of FIG. 7. Thus, descriptions overlapping with the above descriptions provided with reference to FIGS. 1 to 4 will not be provided.

Referring to FIG. 7, the semiconductor package 2000 may further include a second semiconductor chip 600 and a heat dissipation structure 710. The second semiconductor chip 600 and the heat dissipation structure 710 may be arranged on (e.g., in contact from above, in the vertical direction D3) the second redistribution substrate 200. The semiconductor chip 300 may be a first semiconductor chip, and the chip pad 310 may be referred to as a first chip pad. The first semiconductor chip (e.g., semiconductor chip 300) and the second semiconductor chip 600 may be different types of semiconductor chips. For example, the first semiconductor chip (e.g., semiconductor chip 300) may be a logic chip, and the second semiconductor chip 600 may be a memory chip. For example, the first semiconductor chip (e.g., semiconductor chip 300) may be an ASIC, and the second semiconductor chip 600 may be a DRAM. The second semiconductor chip 600 may be disposed on (e.g., may be above) the connection support structure 400. The second semiconductor chip 600 may include a second chip pad 610. A third connection terminal 680 may be interposed between the second chip pad 610 and the second redistribution pattern 220 exposed from the second insulating layer 210. The second semiconductor chip 600 may be electrically connected to the first semiconductor chip (e.g., semiconductor chip 300) through the third connection terminal 680, the second redistribution pattern 220, the vertical conductive pillar 420, the second connection terminal 480, the first redistribution pattern 120, and the first connection terminal 380. The second semiconductor chip 600 may overlap the connection support structure 400 in the third direction D3 (e.g., vertically). Since the second semiconductor chip 600 is disposed at a very short (e.g., minimal) distance from the connection support structure 400, resistance from the third connection terminal 680 and second redistribution pattern 220 may be negligible and thus electrical performance may be improved. The heat dissipation structure 710 may be disposed on the first semiconductor chip (e.g., semiconductor chip 300). The heat dissipation structure 710 may overlap the first semiconductor chip (e.g., semiconductor chip 300) in the third direction D3. The heat dissipation structure 710 may include at least one of a heat sink or a heat slug. The heat dissipation structure 710 may include or may be, for example, metal such as copper or aluminum. For example, the heat dissipation structure 710 may be in the form of a block of material. A heat transfer material layer 720 may be disposed between the heat dissipation structure 710 and the second redistribution substrate 200. The heat transfer material layer 720 may include a thermal interface material (TIM). The heat dissipation structure 710 and the heat transfer material layer 720 may receive heat from the first semiconductor chip (e.g., semiconductor chip 300) and dissipate the heat to the outside. As a result, heat may be easily dissipated during operation of the first semiconductor chip (e.g., semiconductor chip 300), thus improving reliability of the semiconductor package 2000.

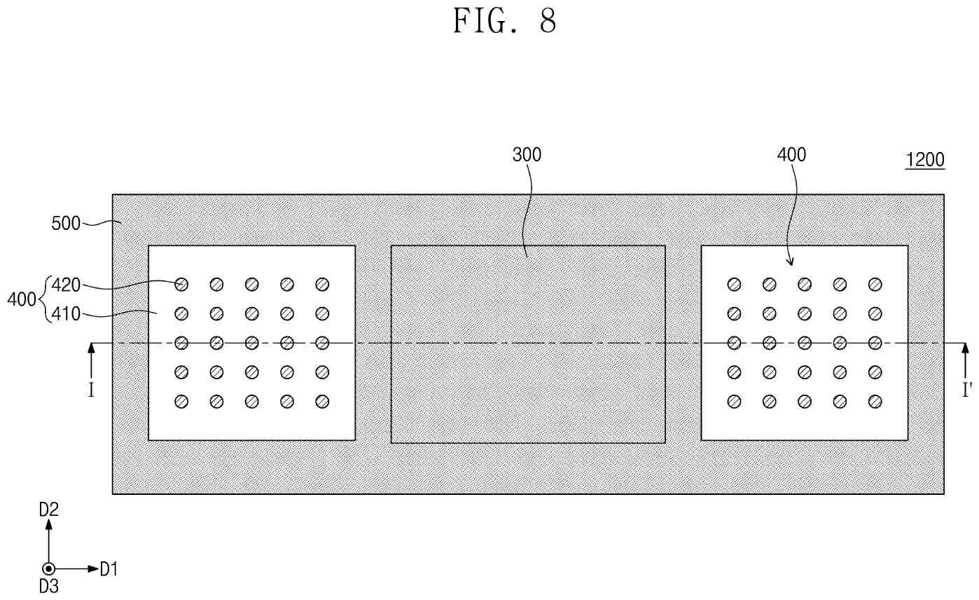

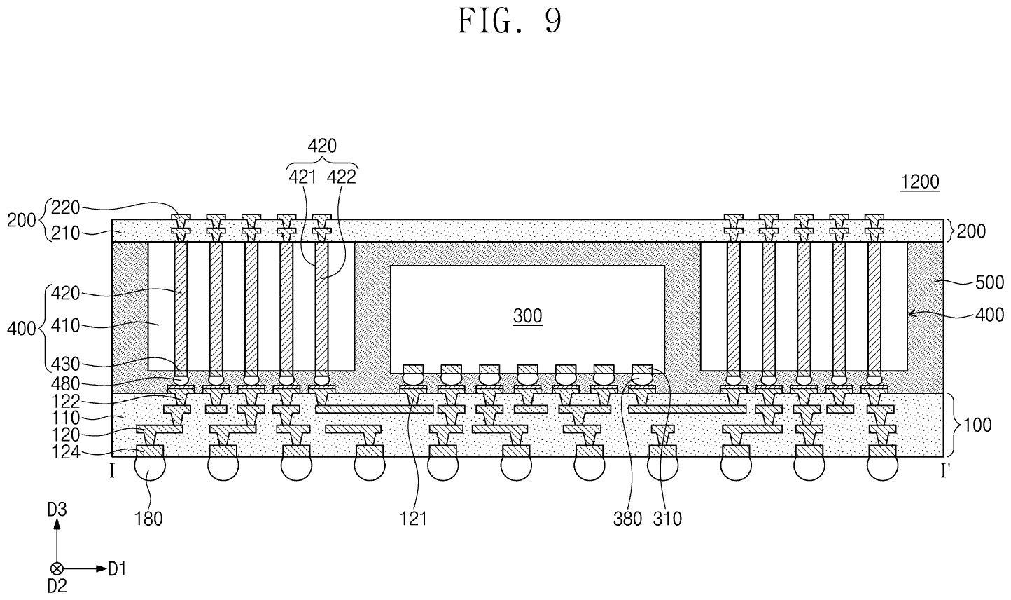

FIG. 8 is a plan view of a semiconductor package 1200 according to some embodiments. FIG. 9 is a cross-sectional view taken along line I-I′ of FIG. 8. Most of the above description with reference to FIGS. 1 and 2 may be applicable in the same or similar manner to the semiconductor package 1200 of FIGS. 8 and 9. Thus, descriptions overlapping with the above descriptions provided with reference to FIGS. 1 and 2 will not be provided.

Referring to FIGS. 8 and 9, the connection support structure 400 may be one of a plurality of connection support structures (e.g., may be provided in plurality). The connection support structures 400, for example, may be arranged spaced apart from each other in the first direction D1 with the semiconductor chip 300 (e.g., the first semiconductor chip) therebetween. As described above with reference to FIG. 7, in some examples there may also be second semiconductor chips 600 (not shown in FIGS. 8 and 9) arranged on the connection support structures 400, respectively.

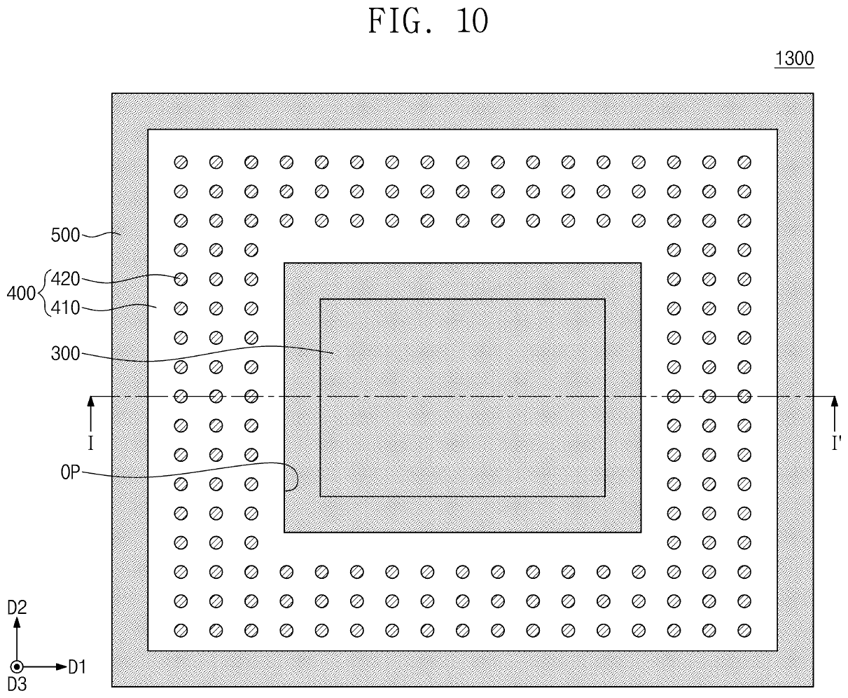

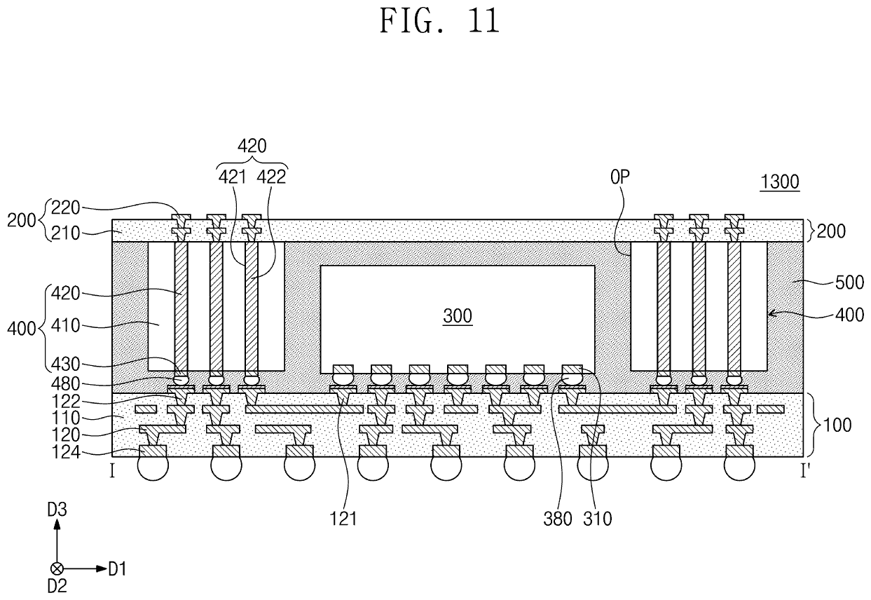

FIG. 10 is a plan view of a semiconductor package 1300 according to some embodiments. FIG. 11 is a cross-sectional view taken along line I-I′ of FIG. 10. Descriptions overlapping with the above descriptions provided with reference to FIGS. 1 and 2 will not be provided.

Referring to FIGS. 10 and 11, the glass substrate 410 of the connection support structure 400 may have a shape of a square ring in a plan view. The glass substrate 410 may have a hole OP penetrating the inside thereof. The semiconductor chip 300 may be disposed in the hole OP. The vertical conductive pillars 420 may be arranged surrounding the semiconductor chip 300. In an example, a square ring-shaped region between the glass substrate 410 and semiconductor chip 300 may contain molding film 500.

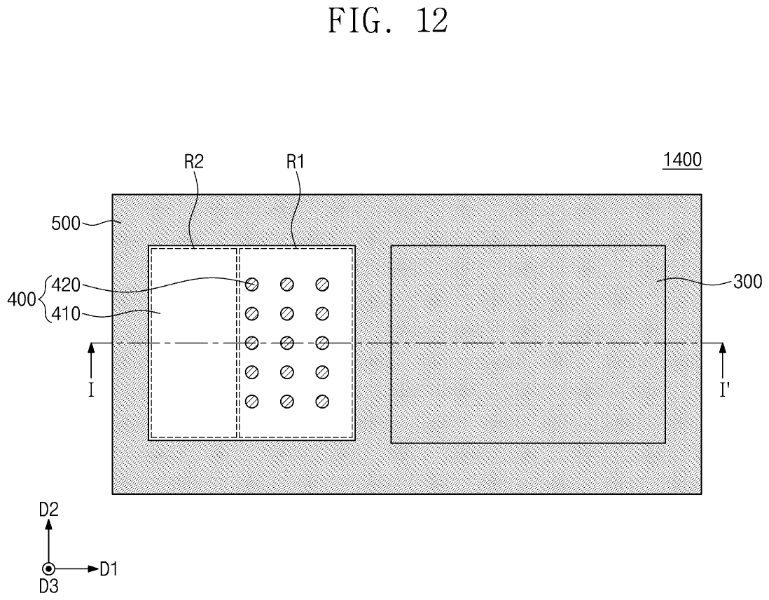

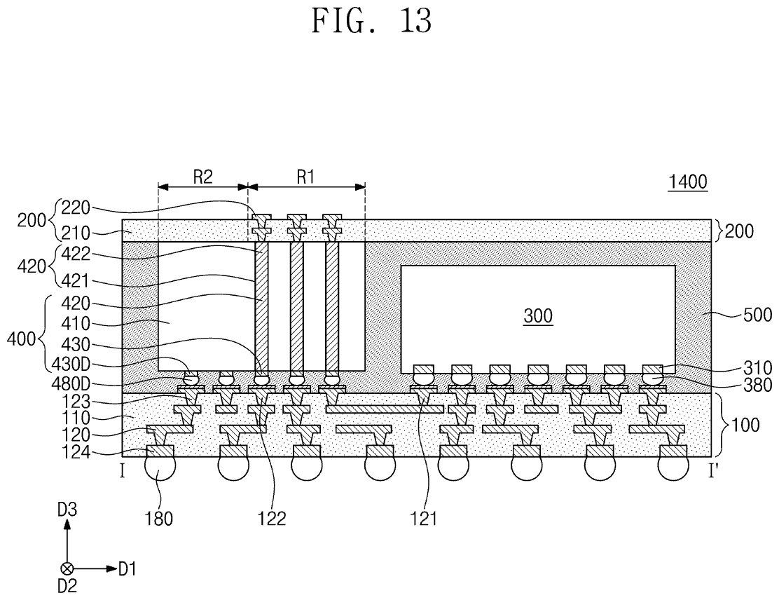

FIG. 12 is a plan view of a semiconductor package 1400 according to some embodiments. FIG. 13 is a cross-sectional view taken along line I-I′ of FIG. 12. Descriptions overlapping with the above descriptions provided with reference to FIGS. 1 and 2 will not be provided.

Referring to FIGS. 12 and 13, the glass substrate 410 may have a first region R1 and a second region R2. The first region R1 may be a region in which the vertical conductive pillars 420 are arranged, and the second region R2 may be a region in which vertical conductive pillars 420 are not arranged. The second region R2 may be referred to as a dummy region. The second region R2 may have a width that is at least two times the pitch P1 or P2 of the vertical conductive pillars 420 in the first direction D1 or the second direction D2. A dummy connection pad 430D and a dummy connection terminal 480D may be arranged on a lower portion of the second region R2, and current may not flow through the dummy connection pad 430D and the dummy connection terminal 480D. The first redistribution substrate 100 may further include a dummy bonding pad 123 disposed at the same level as the first bonding pad 121 and the second bonding pad 122. The dummy bonding pad 123 may be connected or not connected to the first redistribution patterns 120. The dummy connection terminal 480D may be disposed between the dummy bonding pad 123 and the dummy connection pad 430D. Since the glass substrate 410 further includes the dummy region R2, stress due to a difference in the coefficient of thermal expansion may be alleviated during operation of the semiconductor package, and accordingly warpage of the semiconductor package may be reduced.

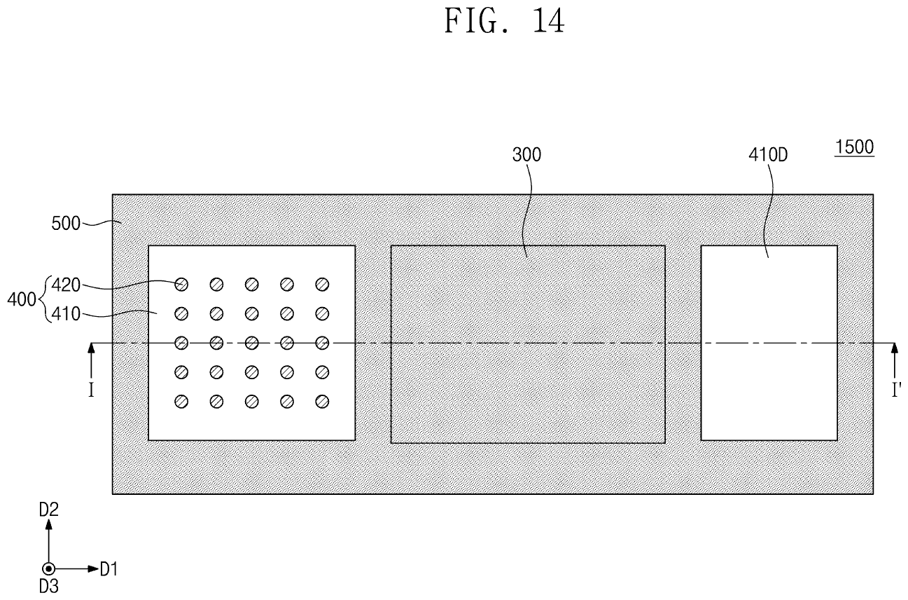

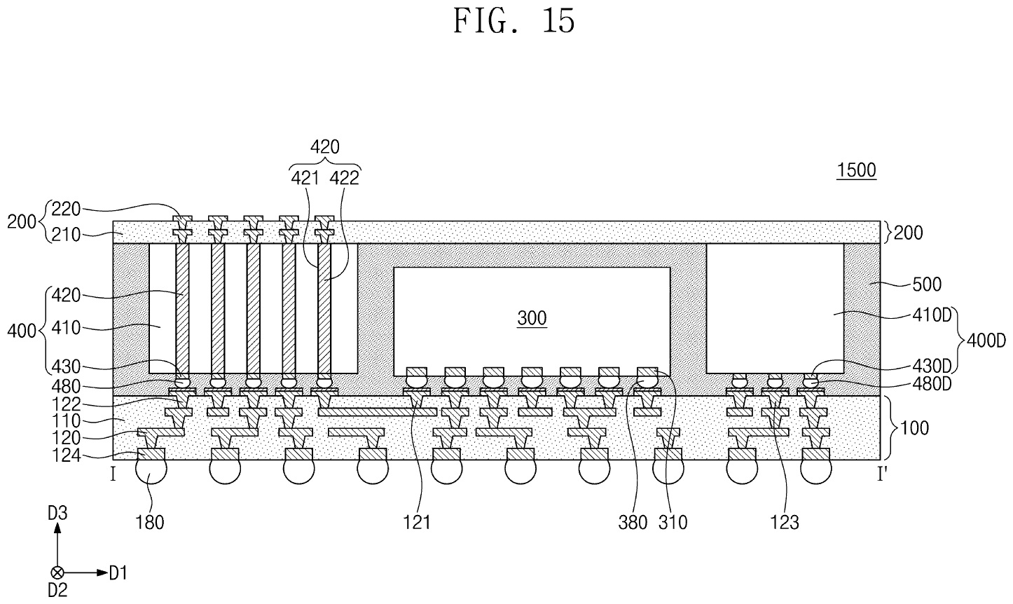

FIG. 14 is a plan view of a semiconductor package 1500 according to some embodiments. FIG. 15 is a cross-sectional view taken along line I-I′ of FIG. 14. Descriptions overlapping with the above descriptions provided with reference to FIGS. 1 and 2 will not be provided.

Referring to FIGS. 14 and 15, the semiconductor package 1500 may further include a dummy support structure 400D. The dummy support structure 400D may further include a glass substrate 410D and the dummy connection pad 430D but may not include a vertical conductive pillar. The dummy connection terminal 480D may be disposed on a lower surface of the dummy connection pad 430D. The dummy support structure 400D may not electrically connect the first redistribution pattern 120 and the second redistribution pattern 220. The dummy support structure 400D may be disposed instead of a portion of the molding film 500. The dummy support structure 400D may alleviate stress due to a difference in the coefficient of thermal expansion, and thereby reduce warpage of the semiconductor package.

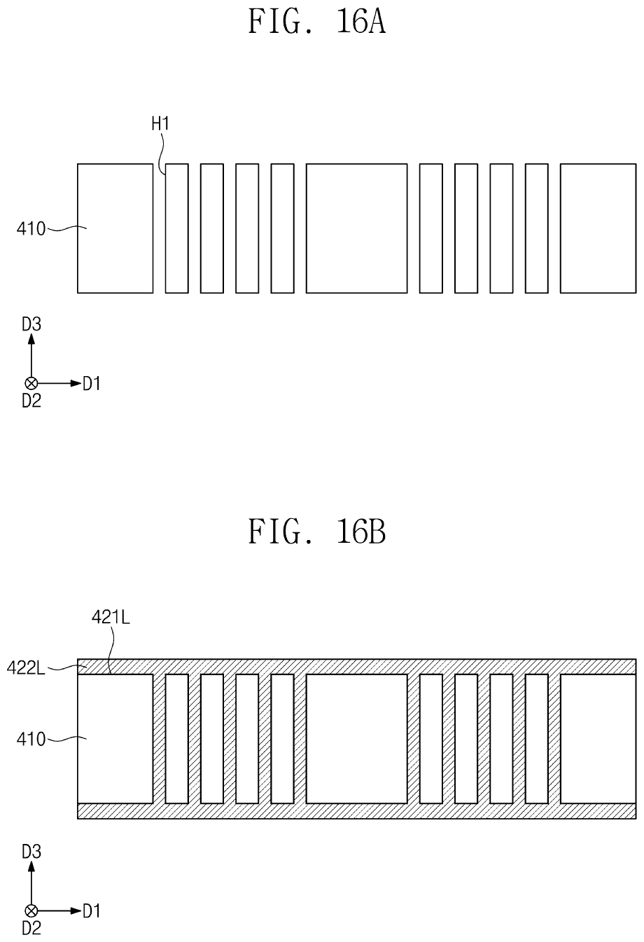

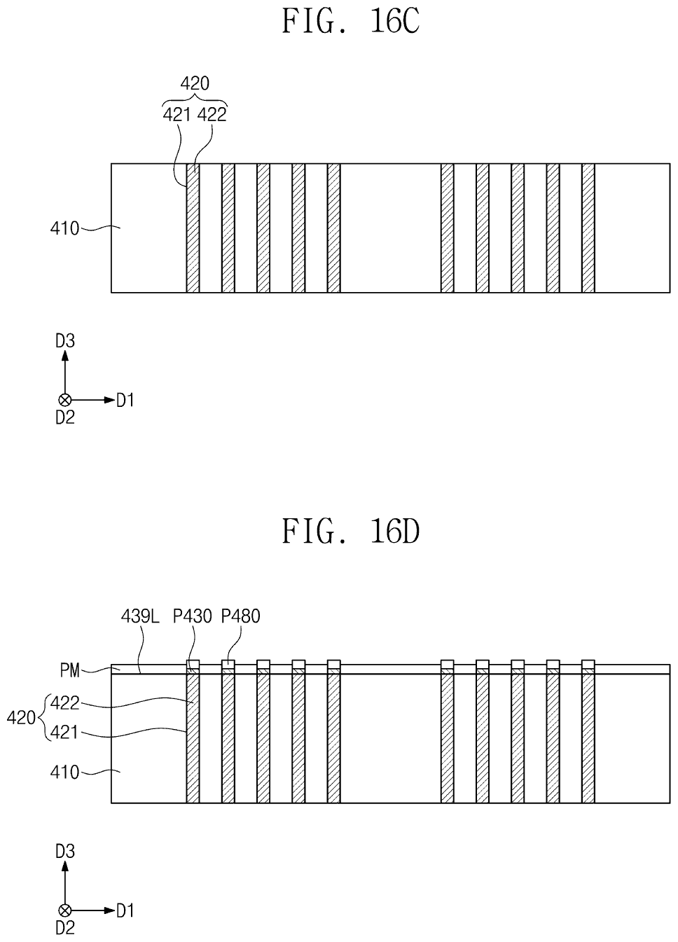

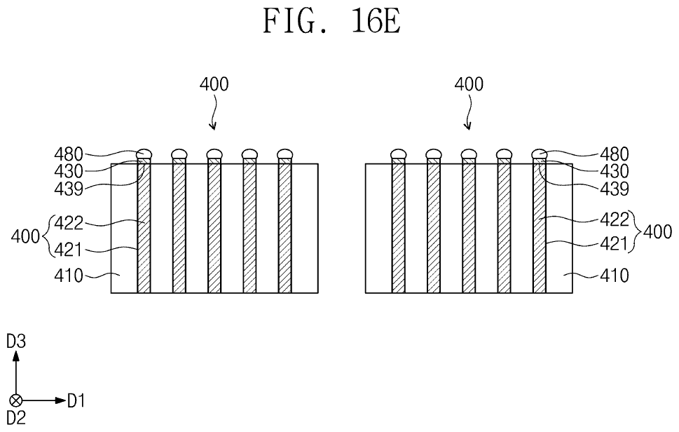

FIGS. 16A, 16B, 16C, 16D, and 16E are diagrams illustrating a manufacturing process of a connection support substrate according to some embodiments.

Referring to FIG. 16A, the glass substrate 410 may be prepared. The glass substrate 410, for example, may have a disc shape such as a wafer. A plurality of holes H1 penetrating the glass substrate 410 may be formed. The holes H1 may each define a region in which a vertical conductive pillar is to be formed. For example, laser drilling may be used to form the holes H1. A pitch of the holes H1 may be, for example, larger than 0 μm and equal to or smaller than about 90 μm, for example, the same as pitch P1 of the vertical conductive pillars.

Referring to FIG. 16B, a first seed layer 421L may be formed on the glass substrate 410. The first seed layer 421L may cover an upper surface and lower surface of the glass substrate 410 (e.g., prior to flipping the glass substrate 410, such as in a flip chip bonding method) and an inner wall of the hole H1. The first seed layer 421L may be formed using a method such as electroless plating, sputtering, and chemical vapor deposition. Thereafter, a first conductive layer 422L may be formed on the first seed layer 421L. For example, the first conductive layer 422L may be formed using an electroplating method in which the first seed layer 421L is used as an electrode. For example, the first seed layer 421L may include copper/titanium, and the first conductive layer 422L may include copper.

Referring to FIG. 16C, surface polishing may be performed on the upper surface 410T and the lower surface 410B (see FIGS. 2 and 6) of the glass substrate 410. The surface polishing may include a process such as chemical mechanical polishing (CMP) or grinding. The vertical seed patterns 421 and the vertical conductive patterns 422 separated from each other may be formed by patterning the first seed layer 421L and the first conductive layer 422L through the surface polishing. For example, the plurality of vertical conductive pillars 420 including the vertical seed pattern 421 and the vertical conductive pattern 422 may be formed. The first seed layer 421L and the first conductive layer 422L on an upper surface of the glass substrate 410 may be all removed.

Referring to FIG. 16D, a second seed layer 439L may be formed on an upper surface of the glass substrate 410 and an upper surface of the vertical conductive pillar 420. The second seed layer 439L may be formed using a method such as electroless plating, sputtering, and chemical vapor deposition. Thereafter, a photoresist pattern PM exposing the upper surface of the vertical conductive pillar 420 and covering the glass substrate 410 may be formed. Forming the photoresist pattern PM may include coating the upper surface of the glass substrate 410 with a photoresist material, and exposing and developing the same. A preliminary connection pad P430 and a preliminary connection terminal P480 may be formed on the second seed layer 439L exposed from the photoresist pattern PM through an electroplating method.

Referring to FIG. 16E, the photoresist pattern PM may be removed. A lower seed pattern may be formed by patterning the second seed layer 439L using the preliminary connection pad P430 and the preliminary connection terminal P480 as an etching mask. As a result, the connection pad 430 including the lower seed pattern 439, the first metal pattern 431, the second metal pattern 432, and the third metal pattern 433 may be formed as illustrated in FIG. 3. The second connection terminal 480 may be formed from the preliminary connection terminal P480 through a reflow process. In addition, the plurality of connection support structures 400 may be formed by sawing the glass substrate 410. The plurality of connection support structures 400 may each be substantially the same as the connection support structure 400 described above with reference to FIG. 3.

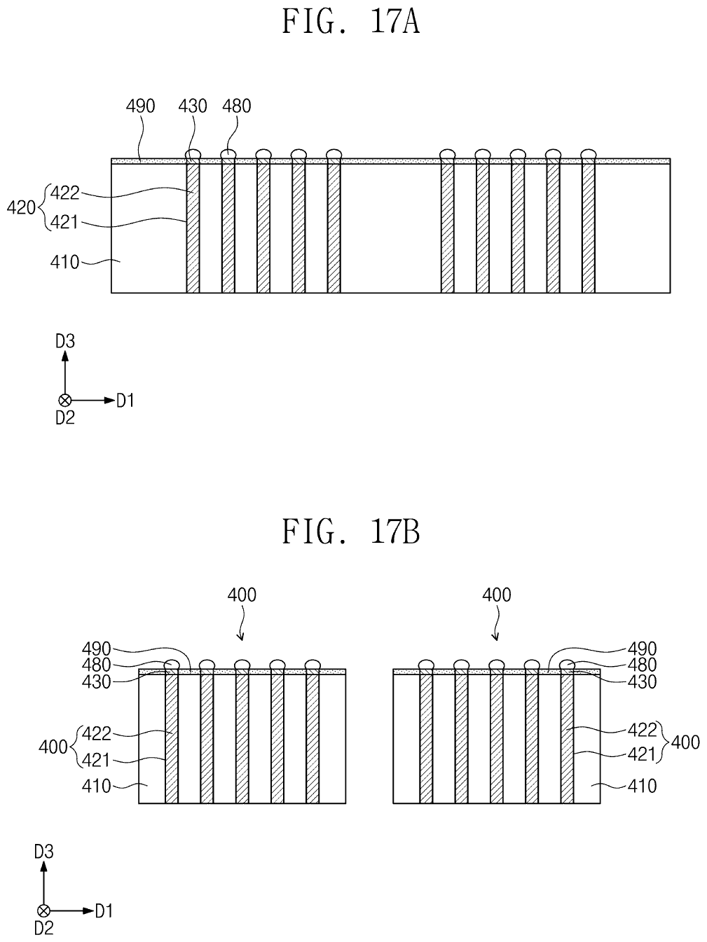

FIGS. 17A and 17B are diagrams illustrating a manufacturing process of a connection support substrate according to some embodiments.

Referring back to FIG. 16A, the holes H1 penetrating the glass substrate 410 may first be formed, and a pitch of the holes H1 may be about 90 μm to about 130 μm. Referring back to FIG. 16B, the first seed layer 421L and the first conductive layer 422L may then be formed on the glass substrate 410. Referring back to FIG. 16C, the vertical seed pattern 421 and the vertical conductive pattern 422 may then be formed by patterning the first seed layer 421L and the first conductive layer 422L.

Referring to FIG. 17A, the protective pattern 490 may then be formed on an upper surface of the glass substrate 410 (e.g., prior to flipping the glass substrate 410). Forming the protective pattern 490 may include coating the upper surface of the glass substrate 410 with a photosensitive solder resist material, and exposing, developing, and curing the same. The connection pad 430 may be formed on the upper surface of the vertical conductive pillar 420 (e.g., prior to flipping) exposed from the protective pattern 490. For example, the connection pad 430 including the first metal pattern 431 and the second metal pattern 432 of FIG. 6 may be formed using an electroless plating method. Thereafter, the second connection terminal 480 may be formed on the connection pad 430. Forming the second connection terminal 480 may include, for example, attaching a solder ball or bump including solder.

Referring to FIG. 17B, in some examples, the plurality of connection support structures 400 may be formed by sawing the glass substrate 410, so as to facilitate forming the vertical conductive pillars with high aspect ratios. The plurality of connection support structures 400 may each be substantially the same as the connection support structure 400 described above with reference to FIG. 6.

According to one embodiment of the inventive concept, a vertical conductive pillar having a high aspect ratio may be formed through a single process by forming the vertical conductive pillar in a hole of a glass substrate. However, in the case where a vertical conductive pillar is formed after forming a hole in a photoresist material, it may be difficult to form a vertical conductive pillar having a high aspect ratio. For example, when a diameter of the hole in the photoresist material is small and a target depth is large, it may be difficult for a developer to sufficiently infiltrate to the depth. Therefore, in some embodiments, a vertical conductive pillar may be divided into portions and a process may be performed multiple times in order to form a vertical conductive pillar having a high aspect ratio through a photoresist material. Accordingly, a connection support structure 400, as in the embodiments of FIGS. 1 through 7, may be formed by sawing the glass substrate 410. Alternatively, a plurality of separate connection support structures 400, as in the embodiments of FIGS. 8 and 9, may be formed from the sawed glass substrate 410. Additionally, the plurality of separate connection support structures 400 in the embodiments of FIGS. 8 and 9 may also be formed from sawed different glass substrates 410.

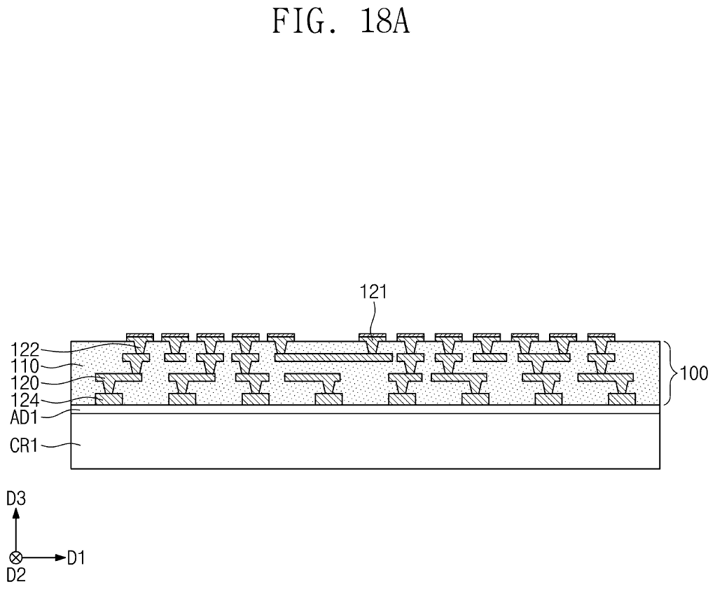

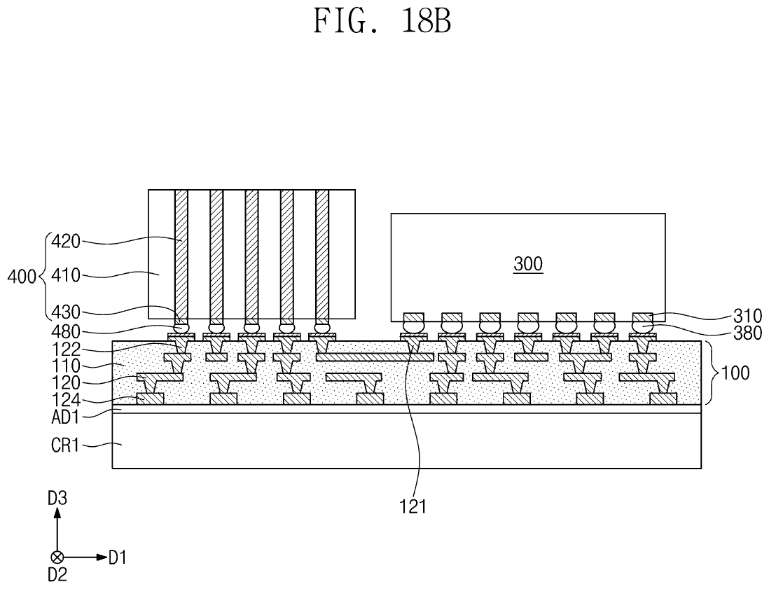

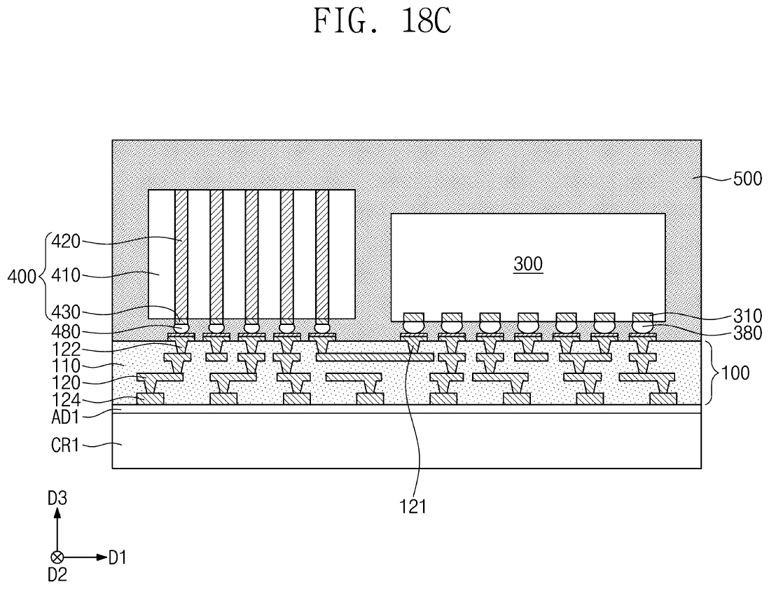

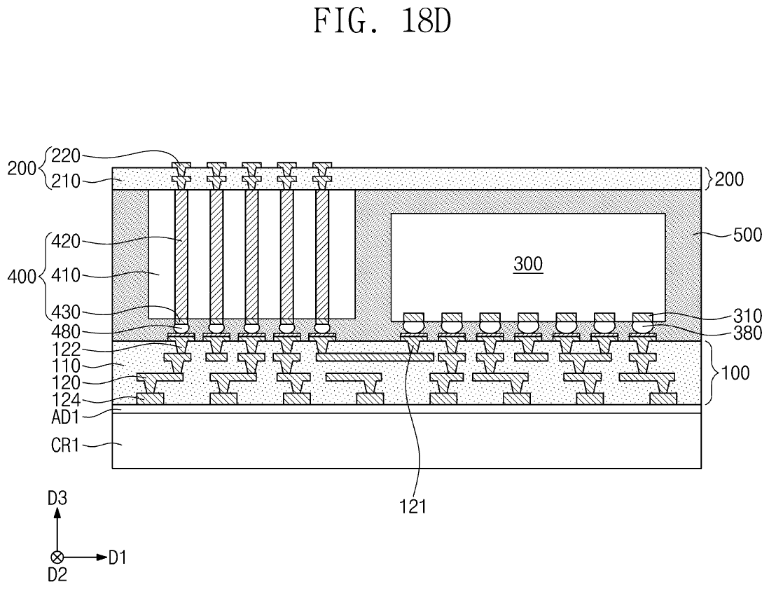

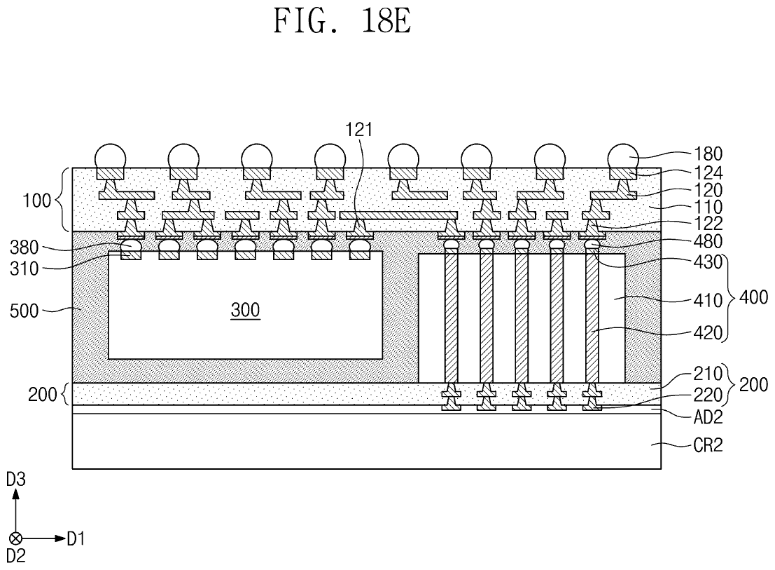

FIGS. 18A, 18B, 18C, 18D, and 18E are diagrams illustrating a manufacturing process of a semiconductor package according to some embodiments.

Referring to FIG. 18A, a first carrier substrate CR1 may be prepared. The first carrier substrate CR1 may be a silicon substrate or glass substrate but is not limited thereto. A first adhesive layer AD1 may be formed on the first carrier substrate CR1. The first adhesive layer AD1 may include, for example, a material such as polyimide. The first redistribution substrate 100 may be formed on the first adhesive layer AD1. In detail, a photosensitive material layer may be formed by applying a photosensitive material. A space in which the under bump pattern 124 is to be formed may be formed by patterning the photosensitive material layer through exposure, development, and curing processes. A seed layer may be formed on the patterned photosensitive material layer. A photoresist pattern may be formed in a region of the photosensitive material layer except for another region thereof in which the under bump pattern is to be formed. A first conductive pattern may be formed on the seed layer using an electroplating method. The photoresist pattern may be removed, and the seed layer may be patterned using the first conductive pattern as an etching mask. As a result, the under bump pattern including a first seed pattern and the first conductive pattern may be formed. Similarly to a method of forming the under bump pattern, the first redistribution pattern 120, the first bonding pad 121, and the second bonding pad 122 may be formed. The first insulating layer 110 may be formed by repeating forming of the photosensitive material layer.

Referring to FIG. 18B, the semiconductor chip 300 may be mounted on the first redistribution substrate 100. For example, the semiconductor chip 300 may be disposed on the first redistribution substrate 100 using a flip chip bonding method. The semiconductor chip 300 may be coupled to the first bonding pads 121 using the first connection terminal 380. The connection support structure 400 may be mounted at a position spaced apart from the semiconductor chip 300 in the first direction D1. The connection support structure 400 may be coupled to the second bonding pads 122 using the second connection terminal 480. For example, the connection support structure 400 may be the connection support structure 400 formed through a single process, as in the example of FIG. 16E, or the connection support structure 400, formed with a sawing step, as in the example of FIG. 17B.

Referring to FIG. 18C, the molding film 500 may be formed on the first redistribution substrate 100. Forming the molding film 500 may include heating an EMC to liquefy the EMC, injecting the liquid EMC on the first redistribution substrate 100 and curing the same. The liquid EMC may be injected so as to cover an upper surface and side surface of the semiconductor chip 300 and an upper surface and side surface of the connection support structure 400 and fill a gap between a lower surface of the semiconductor chip 300 and an upper surface of the first redistribution substrate 100 and a gap between a lower surface of the connection support structure 400 and the upper surface of the first redistribution substrate 100.

Referring to FIG. 18D, the upper surface of the connection support structure 400 may be exposed by partially removing the molding film 500. Partially removing the molding film 500 may include, for example, a grinding process. During the grinding process, an upper portion of the connection support structure 400 may be removed. As a result of the grinding process, the upper surface of the connection support structure 400 may be coplanar with an upper surface of the molding film 500. The second redistribution substrate 200 may be formed on the exposed upper surface of the connection support structure 400 and the upper surface of the molding film 500. The second insulating layer 210 may be formed using a method that is the same as or similar to the above method of forming the first insulating layer 110. The second redistribution pattern 220 may be formed using a method that is the same as or similar to a method of forming the first redistribution pattern 120.

Referring to FIGS. 18D and 18E, a second carrier substrate CR2 may be prepared. A second adhesive layer AD2 may be disposed on the second carrier substrate CR2, and an upper surface of the second redistribution substrate 200 may be attached to the second adhesive layer AD2. For example, the second carrier substrate CR2 may be on an opposite side of the semiconductor package assembly from the first carrier substrate CR1 along the vertical direction D3. Thereafter, the first carrier substrate CR1 and the first adhesive layer AD1 may be removed. After the first adhesive layer AD1 is removed, a plasma cleaning process or the like may be additionally performed on a lower surface of the first redistribution substrate 100. An exposed portion of the first seed pattern of the under bump pattern 124 may be removed.

In one embodiment, the semiconductor package assembly may be flipped vertically (e.g., in a flip chip bonding method), for example after the exposed portion of the first seed pattern is removed. The external connection terminal 180 may be formed on the under bump pattern 124. Referring back to FIG. 2, the second redistribution substrate 200 may be detached from the second adhesive layer AD2. As a result, the semiconductor package 1000 or 1100 may be formed.

In addition, referring to FIG. 7, the second semiconductor chip 600 may be mounted on the second redistribution substrate 200 vertically overlapping the connection support structure 400. The heat dissipation structure 710 may be attached to the second redistribution substrate 200 vertically overlapping the first semiconductor chip (e.g., semiconductor chip 300).

A semiconductor package according to the inventive concept may use a glass substrate instead of a portion of a molding film. The disclosed glass substrate may provide advantages, such as having more similar material properties to a semiconductor chip compared with the portion of molding film or a copper post region. For example, since a difference in the coefficient of thermal expansion between the glass substrate and an adjacent semiconductor chip is small, occurrence of warpage of the disclosed semiconductor package may be reduced or eliminated. As a result, operational reliability of the semiconductor package may be improved. Furthermore, a vertical conductive pillar may be formed in a hole penetrating the glass substrate. As a result, a vertical conductive pillar having a high aspect ratio may be effectively formed, and thus, the disclosed glass substrate may also provide significant freedom in TGV design.

Although the embodiments of the present invention have been described, it is understood that the present invention should not be limited to these embodiments but various changes and modifications can be made by one ordinary skilled in the art within the spirit and scope of the present invention as hereinafter claimed.

What is claimed is:

1. A semiconductor package comprising:
a first redistribution substrate;
a semiconductor chip and a connection support structure on the first redistribution substrate, wherein the semiconductor chip is a logic chip or a memory chip; and
a molding film above the first redistribution substrate,
wherein the connection support structure is horizontally spaced apart from the semiconductor chip and horizontally overlaps the semiconductor chip, and
wherein the connection support structure includes:
a glass substrate; and
a vertical conductive pillar penetrating the glass substrate.

2. The semiconductor package of claim 1, wherein a highest level of the glass substrate is higher than a highest level of the semiconductor chip.

3. The semiconductor package of claim 1, wherein the vertical conductive pillar includes:
a vertical seed pattern; and
a vertical conductive pattern on the vertical seed pattern, and
wherein the vertical conductive pattern is spaced apart from an inner wall of the glass substrate with the vertical seed pattern therebetween.

4. The semiconductor package of claim 1, wherein the connection support structure is one of a plurality of connection support structures.

5. The semiconductor package of claim 1,
wherein the glass substrate includes a hole penetrating vertically therethrough, and
the semiconductor chip is disposed in the hole.

6. The semiconductor package of claim 1, wherein an upper surface of the glass substrate is coplanar with an upper surface of the vertical conductive pillar.

7. The semiconductor package of claim 1, wherein an upper surface of the glass substrate is coplanar with an upper surface of the molding film.

8. The semiconductor package of claim 1, wherein an aspect ratio of the vertical conductive pillar is larger than 3.

9. The semiconductor package of claim 1, wherein a height of the vertical conductive pillar is between 50 μm and 250 μm.

10. The semiconductor package of claim 1,
wherein the glass substrate includes a first region and a second region,
the vertical conductive pillar is one of a plurality of vertical conductive pillars,
the plurality of vertical conductive pillars are arranged in the first region,
the plurality of vertical conductive pillars are not arranged in the second region,
the plurality of vertical conductive pillars are spaced within the first region according to a first pitch, and
a horizontal width of the second region is larger than two times the first pitch.

11. The semiconductor package of claim 1, further comprising
a dummy support structure disposed on the first redistribution substrate and horizontally spaced apart from the semiconductor chip,
wherein the dummy support structure includes a second glass substrate.

12. The semiconductor package of claim 1,
wherein the vertical conductive pillar is one of a plurality of vertical conductive pillars,
the plurality of vertical conductive pillars are spaced according to a first pitch,
the first pitch is larger than 0 μm and equal to or less than 90 μm,
and the semiconductor package further comprises:
a connection pad on a lower surface of the vertical conductive pillar; and
a connection terminal on the connection pad,
wherein the connection terminal is interposed between the first redistribution substrate and the connection pad, and
a thickness of the connection terminal is larger than a thickness of the connection pad and equal to or smaller than two times the thickness of the connection pad.

13. The semiconductor package of claim 12, wherein the molding film covers a side surface of the connection terminal and is in contact with a lower surface of the glass substrate.

14. The semiconductor package of claim 1, wherein:
the vertical conductive pillar is one of a plurality of vertical conductive pillars,
the plurality of vertical conductive pillars are spaced according to a second pitch,
the second pitch is larger than 90 μm and equal to or less than 130 μm,
and the semiconductor package further comprises:
a connection pad on a lower surface of the vertical conductive pillar; and
a connection terminal on the connection pad,
wherein the connection terminal is interposed between the first redistribution substrate and the connection pad, and
wherein a thickness of the connection terminal is at least seven times larger than a thickness of the connection pad.

15. The semiconductor package of claim 14, further comprising
a protective pattern on a lower surface of the glass substrate,
wherein the protective pattern includes a solder resist material, and
wherein the molding film is in contact with a lower surface of the protective pattern.

16. A semiconductor package comprising:
a first redistribution substrate;
a semiconductor chip and a connection support structure on the first redistribution substrate, wherein the semiconductor chip is a logic chip or a memory chip;
a second redistribution substrate on the semiconductor chip and the connection support structure; and
a molding film between the first redistribution substrate and the second redistribution substrate,
wherein the connection support structure is horizontally spaced apart from the semiconductor chip and horizontally overlaps the semiconductor chip, and
wherein the connection support structure includes:
a glass substrate; and
a vertical conductive pillar penetrating the glass substrate,
wherein an upper surface of the glass substrate is in contact with a lower surface of the second redistribution substrate, and
wherein a lower surface of the glass substrate is spaced apart from an upper surface of the first redistribution substrate.

17. The semiconductor package of claim 16, further comprising:
a connection terminal including solder disposed between the lower surface of the glass substrate and the upper surface of the first redistribution substrate,
wherein the molding film covers a side surface of the connection terminal.

18. The semiconductor package of claim 17,
wherein an aspect ratio of the vertical conductive pillar is larger than 3, and
a height of the vertical conductive pillar is between 50 μm and 250 μm.

19. The semiconductor package of claim 17, wherein the molding film extends between the glass substrate and the first redistribution substrate.

20. A semiconductor package comprising:
a first redistribution substrate;
a first semiconductor chip and a connection support structure on the first redistribution substrate, wherein the semiconductor chip is a logic chip or a memory chip;
a second substrate on the first semiconductor chip and the connection support structure;
a molding film between the first redistribution substrate and the second substrate;
a second semiconductor chip and a heat dissipation structure on the second substrate;
a first connection terminal between the first semiconductor chip and the first redistribution substrate; and
a second connection terminal between the connection support structure and the first redistribution substrate,
wherein the connection support structure is horizontally spaced apart from the first semiconductor chip,
wherein the heat dissipation structure is horizontally spaced apart from the second semiconductor chip, and
wherein the connection support structure includes:
a glass substrate; and
a vertical conductive pillar penetrating the glass substrate, wherein
the heat dissipation structure vertically overlaps the first semiconductor chip, and
wherein the molding film covers an upper surface and a lower surface of the first semiconductor chip, a side surface of the connection support structure, a side surface of the first connection terminal, and a side surface of the second connection terminal.
